(19) United States
(12) Patent Application Publication
(10) Pub. No.: US 2011/0140730 A1
(43) Pub. Date: Jun. 16, 2011

(54) DETECTION CIRCUITRY FOR DETECTING BONDING CONDITIONS ON BOND PADS

(75) Inventors: Victor Zieren, Valkensward (NL); Harold Geradus Pieter Hendrikus Benten, Waalre (NL); Agnese Antonietta Maria Bargagli-Stoffi, Eindhoven (NL); Marcel Pelgrom, Helmond (NL); Hendricus Joseph Maria Veendrick, Heeze (NL)

(73) Assignee: NXP B.V., Eindhoven (NL)

(21) Appl. No.: 12/995,445

(22) PCT Filed: May 14, 2009
(86) PCT No.: PCT/IB09/51991

§ 371 Date: Nov. 30, 2010

(30) Foreign Application Priority Data
May 30, 2008 (EP) 08104174.1

(51) Int. Cl. G01R 31/26

(52) U.S. Cl. 324/762.03

(57) ABSTRACT

The present invention relates to a detection circuitry for detecting bonding conditions on segmented bond pads of a semiconductor device, the bonding conditions representing good or bad contacts on the bond pads. The detection circuitry comprises a segmented bond pad (1, 11) having at least two parts (2, 3, 12, 13) being electrically separated from each other, and a supplying unit (S1, S2, R1, R2) being adapted for supplying predetermined signals to at least one of the at least two parts of the segmented bond pad. Furthermore, a detector (4, 14) is provided for receiving from at least one of the at least two parts of the segmented bond pad sensing signals derived from said predetermined signals, and for determining the bonding conditions based on said received sensing signals indicative of a good or bad bonding contact on the segmented bond pad.

### FIELD OF THE INVENTION

The present invention relates to the field of detection of bonding conditions, and in particular to a detection circuitry for detecting bonding conditions on bond pads of a semiconductor device.

### BACKGROUND OF THE INVENTION

In advanced packages including one or more semiconductor devices many hundreds to thousands of connections are made per integrated circuit (IC). Connections are usually made by bonding, and a common technology is the bump-ball or solder-ball technique. When this technique is applied, little balls of conductive material are formed on top (that is, on the upper surface) of the bond pads of the die and are spread out over the surface. On a printed circuit board (PCB) or on a second IC a similar but mirrored pattern is constructed. Now the attachment (connection) is realized by placing the IC upside down on the PCB and applying a thermal step to ensure that the connections are made. Just as in all technical machinery every now and then a connection is not formed. As a result of the missing signal connection from one IC via the PCB to a second IC, the communication is broken, and such a malfunction or wire disconnection is detectable by boundary scan methods. To perform boundary scan methods, the IC or package is connected to a corresponding test equipment and operated based on a specific test software.

A bonding pad test configuration is disclosed in reference U.S. Pat. No. 6,229,206 B1. The corresponding test configuration includes a circuit for establishing whether or not a semiconductor chip is correctly bonded by evaluating a state of a bond between a bonding wire and the bonding pad. The circuit of the semiconductor chip uses signals which are derived from at least two parts of the segmented bonding pad to determine, if the bonding wire is in contact with the at least two parts. Specifically, a resistance between the at least two parts of the bonding pad is checked for determining whether or not the bonding wire is connected to the two parts of the bonding pad. The circuit includes transistors and an inverter for evaluating the signals derived from the at least two parts of the bonding pad. The circuit can activate and deactivate operating and test modes in dependence on the state of the bond determined by the circuit.

In large PCB or in PCBs with expensive components, it is not economical to dispose of the entire PCB because one connection is not made. However, when an improper or broken connection is detected, in order to rework a PCB concerned the question is: which of the IC has the faulty solder-ball? When in general reworking a PCB having a broken connection or a connection not made, today about 50% of the repair work starts with the wrong IC being removed. Except for the obvious extra work, the second attachment of the originally correctly sampled IC is again a yield factor. It is therefore appropriate to detect the faulty condition of an improper connection or a connection not made. In general, two failure reasons are dominant in case of a PCB situation: the attachment between the layer of the PCB and the bump is not formed, for example, because of corrosion of the layer of the PCB, or the bump is not properly attached to the bond pad on the IC. The last reason will apply to a die-on-die attachment.

FIGS. 1a to 1c show a conventional bond pad for bump attachment. According to FIG. 1a, which shows the cross-sectional view of the conventional bond pad indicates a bump or a solder-ball on the upper surface of the bond pad. It can further be seen from FIG. 1a that the bump or solder-ball has a close contact to the material of the bond pad. This represents a proper attachment of the bump or solder-ball.

According to the cross-sectional representation of FIG. 1b the bump or solder-ball on the top or upper surface of the bond pad is suitably formed but there is no or no sufficient contact between the bump or solder-ball and the pad. The cross-sectional representation of FIG. 1c also shows an insufficient and unreliable attachment of the bump to a conventional bond pad.

It is therefore an object of the present invention to provide a detection circuitry which ensures reliable on-chip detection of bonding conditions of bad or insufficient bond pad contacts.

According to the present invention this object is accomplished by a detection circuitry for detecting bonding conditions according to the appended claims.

In an aspect of the present invention a detection circuitry is presented for detecting bonding conditions on bond pads of a semiconductor device, including a segmented bond pad having at least two parts being electrically separated from each other, a supplying unit being adapted for supplying predetermined signals to at least one of the at least two parts of the segmented bond pad, and a detector being adapted for receiving from at least one of the at least two parts of the segmented bond pad sensing signals derived from the predetermined signals and determining the bonding conditions based on the received sensing signals.

The present invention therefore provides a detection circuitry which allows the reliable and easy checking of the actual binding condition of bonding pads. The bonding pads having a segmented layout are examined by the circuitry on the semiconductor device so that without further detection means a reliable detection result can be obtained. The detection circuitry may easily be compatible with an on-chip boundary scan system, exhibiting a complete on-chip detection solution. The detection result obtained can be supplied to any device outside the semiconductor device for further data evaluation.

Preferred embodiments are defined in the dependent subclaims. Accordingly, the predetermined signals supplied by the supplying unit may include different voltage signals to be supplied to the at least two parts of the segmented bond pad to obtain different potentials between the at least two parts.

The segmented bond pad may include at least a first and a second part, and at least one of the first and second part may be connectable to a boundary scan circuit arranged on the semiconductor device.

The supplying unit may comprise switching elements assigned to each of the at least two parts of the segmented bond pad and be adapted to supply the predetermined signals to the parts of the segmented bond pad assigned thereto, when the switching elements are closed.

The detector may comprise at least two input terminals, and the supplying unit may comprise switching elements assigned to each of the at least two parts of the segmented bond pad and being adapted to supply the predetermined signals to the parts of the segmented bond pad assigned thereto and to connect at least one of the input terminals of the detector with one of the parts of the segmented bond pad, when the switching elements are closed. The detector may be adapted for carrying out a comparison process for comparing the received sensing signals, and to generate a detection signal indicative of the detected bonding condition. Moreover, the detection signal output by the detector may indicate a good bonding condition of the bond pad when the sensing signals of each of the at least two parts of the segmented bond pad have the same logical level.

The supplying unit may be adapted for supplying two different voltage signals via series resistors to the at least two parts of the segmented bond pad. Furthermore, the at least two parts of the segmented bond pad may include at least an inner part and an outer part surrounding fully or at least partially the inner part of the segmented bond pad.

In particular, the detector may comprise a logical EXOR gate. The detector may further be adapted for receiving the sensing signal from one of the at least two parts of the segmented bond pad and may comprise an inverter.

The detector may include at least two input terminals, and the segmented bond pad may be adapted for connection to at least two power conductor units for providing the predetermined signals, and at least one of the input terminals of the detector may be connected to one of the at least two power conductor units.

A switching element may be provided, and the detector may include an S-latch circuit, and from one of the at least two parts of the segmented bond pad via the switching element a sensing signal of the part may be supplied to the detector when the switching element is closed.

Moreover, a switching element may be provided, and one of the at least two parts of the bond pad may be supplied with one of the predetermined signals, and the detector may include a latch circuit which may be supplied via the switching element with the sensing signal of the other part of the at least two parts of the bond pad when the switching element is closed, and may generate a detection signal indicative of the bonding condition. Alternatively, the latch circuit may be one of an S-latch and an R-latch.

Still other advantages of the presently disclosed apparatus will become readily apparent from the following detailed description, figures and examples, which are not intended to limit the scope of the invention. As will be realized, examples illustrated herein are capable of other and different embodiments, and their several details are capable of modifications in various obvious respects, all without departing from the disclosure. Accordingly, the drawings and the description are to be regarded as illustrative in nature, and not as restrictive.

### BRIEF DESCRIPTION OF THE DRAWINGS

The accompanying drawings, which are incorporated in and constitute part of the specification illustrate exemplary embodiments, and

FIGS. 1a, 1b and 1c show a cross-sectional view of a conventional bond pad and corresponding bump or solder-ball,

FIGS. 1d, 1e and 1f show a cross-sectional view of partitioned or segmented bond pads and corresponding bump or solder-ball,

FIGS. 1g, 1h, 1i and 1k show the schematic top view of bond-pad variations according to the present invention,

FIG. 2 shows a basic arrangement of an input bond pad according to a first embodiment of the present invention,

FIGS. 3a and 3b show a schematic block diagram of the circuitry of an input bond pad and an output bond pad according to the present invention,

FIGS. 4a and 4b show the arrangement of bond pads for power supply voltages Vdd and Vss,

FIGS. 5a and 5b show a block arrangement of the circuitry of an input bond pad and an output bond pad according to a second embodiment of the present invention,

FIGS. 6a and 6b show further details of the circuitry of FIGS. 5a and 5b, including an inverter and switching elements according to the second embodiment of the present invention,

FIGS. 7a and 7b show a block arrangement of the circuitry of an input bond pad and an output bond pad according to a third embodiment of the present invention,

FIGS. 8a and 8b show a block arrangement of the circuitry of an input bond pad and an output bond pad according to a fourth embodiment of the present invention,

FIGS. 9a and 9b show block arrangements of the circuit of an input bond pad according to a fifth embodiment of the present invention,

FIGS. 10a and 10b show a block arrangement of the circuitry of power supply pads for voltages Vdd and Vss according to the fifth embodiment of the present invention,

FIGS. 11a and 11b show a block arrangement of the circuitry of an input bond pad and an output bond pad according to a sixth embodiment of the present invention, and

FIGS. 12a and 12b show a block arrangement of the circuitry of power supply bond pads for voltages Vdd and Vss according to sixth embodiment of the present invention.

### DETAILED DESCRIPTION OF THE ILLUSTRATIVE EMBODIMENTS

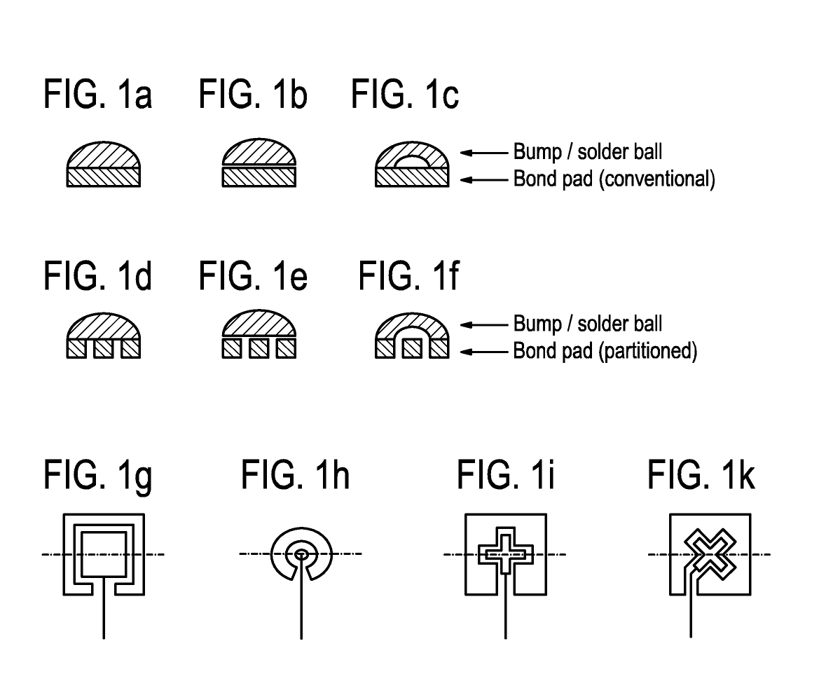

The arrangements shown in FIGS. 1d to 1f indicate cross-sectional representations of bond pads provided for receiving a bump or solder-ball on the top or upper surface of the bond pads. Each of the bond pads shown in FIGS. 1d to 1f are partitioned or segmented, that is, divided up into a plurality of portions, and in a similar manner as it is shown in FIGS. 1a to 1c, a corresponding bump or solder-ball as shown is arranged on the upper surface of the bond pads.

Specifically, the representation in FIG. 1d shows a partitioned or segmented bond pad having received a bump or solder-ball with an appropriate shape. Hence, this representation shows different bonding conditions in conjunction with bond pads of a semiconductor device. The bump or solder-ball has a close (proper, sufficient) contact to the segmented bond pad, that is, the solder-ball or bump contact preferably all the parts of the segmented bond pad. In contrast thereto, the bump or solder-ball according to FIG. 1e, although appropriately shaped, has no contact at all or no sufficient or reliable contact to the segmented bond pad, resulting in a bad contact, that is, a bad bonding condition. Such a bad contact cannot be detected by optical inspection as the bump or solder-ball basically has an appropriate shape. The property of such an insufficient contact may also degrade or will disengage or loosen when the semiconductor device is in operation, thereby also degrading the function of the electronic circuit of the semiconductor device.

Also in the case of FIG. 1f the bad bonding condition caused by the improper or insufficient contact of the solder-ball to the partitioned or segmented bond pad can hardly be seen by optical inspection.

The bonding pads, as for example shown in FIGS. 1d to 1f may be a standard library bond pad of a design system for any application (such as RF or digital application). In contrast to the bond pad arrangements shown in FIGS. 1a to 1f, FIGS. 1g to 1k show the top view of examples of a specific structure of the bond pads according to the present invention. Specifically, the bond pads according to the present invention include a structure which is patterned in the top layer (metal layer) of the bond pad. This structure (or a combination of structures or differently shaped structures) is isolated from the original bond-pad metal layer. That is, according to FIGS. 1g to 1k the pad area is patterned to provide at least two parts. The layout of the bond pattern therefore includes at least an inner part and an outer part (inner and outer portion) of the pad. These at least two parts of the bond pad are electrically separated from each other, but are provided for receiving the bump or solder ball after bonding.

As the pad area is patterned (segmented) to obtain at least two parts, and specifically for example at least an inner part and an outer part as shown in FIGS. 1g to 1k, the outer part surrounding fully or at least partially the inner part of the segmented bond pad. The at least two parts may be used to detect the bonding condition of the segmented bond pad, and specifically a bad contact which occurs in case an insufficient bump or solder-ball is made.

For the detection of the insufficient contact the part of the partitioned bond pad is connected to a detector which will be described hereinafter.

The construction of the at least two (or more) parts maintains sufficient mechanical strength during and after attaching a bonding wire or a solder-ball.

Regarding FIG. 1g, the partitioned or segmented pad having at least two parts or portions consists of a basically quadratic or rectangular inner portion, as well as an outer portion which is basically C-shaped to partly surround the inner portion with a certain distance which ensures an electrical separation (isolation) between the plural parts of the partitioned or segmented bond pad.

A circular structure is shown in FIG. 1h wherein the outer part of the at least two parts of the bond pad is basically ring-shaped and has a discontinuation to partly surround the inner portion with a certain distance. The arrangement of FIG. 1i shows a basically cross-shaped inner part of the segmented pad having at least two parts. The outer part surrounding the cross-shaped inner part has corresponding recessed portions to accommodate the cross-shaped inner part in conjunction with the necessary electrical separation between the various parts of the bond pad.

A corresponding design of the structure of the bond pad according to the present invention is shown in FIG. 1k, wherein the cross-shaped inner part is arranged in a manner rotated by a predetermined angle in comparison to the arrangement shown in FIG. 1i. The outer part of the bond pad is provided in a corresponding manner including the necessary recessed portions for accommodating the inner part.

### First Embodiment

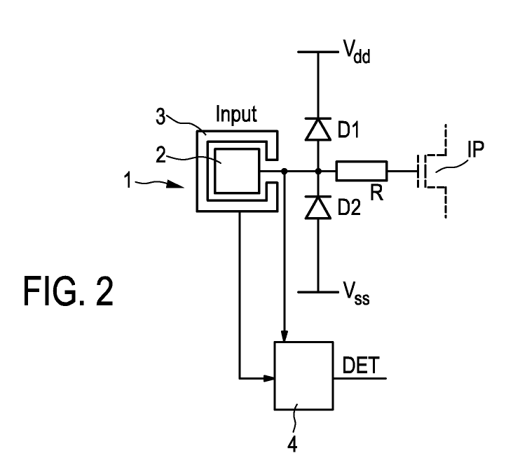

A circuitry for detecting bonding conditions, and in particular bad contacts on bond pads of a semiconductor device according to a first embodiment of the present invention is shown in FIG. 2.

The arrangement shown in FIG. 2 is directed to an input pad 1 of an integrated circuit IP on a semiconductor device. The input pad is provided in the form of a segmented or partitioned bond pad including at least two parts, such as an inner part 2 and an outer part 3. The outer part 3 partly surrounds the inner part 2 of the input pad 1 and forms the complete bond pad wherein the at least two parts are electrically separated from each other. The present invention is not limited to the number of two parts of the bond pad, as the partitioned or segmented bond pad may have more than two parts (segments).

According to this embodiment, the inner part 2 (which basically constitutes a central part of the bond pad) is basically a metal part with, for example, a square shape or rectangular shape, and a C-ring forms the outer part 3 surrounding the inner (central) part 2 and is arranged in the same metal layer on the semiconductor device. The circuitry includes a detector (detecting means) 4 which has at least two input terminals; one input terminal connected to the inner part 2 and the other connected to the outer part 3 of the input pad 1. The input pad 1 is connected to a ESD protection circuit (electrical static discharge protection circuit) which is schematically indicated by two reverse-bias diodes D1 and D2 and the resistor R. The resistor R is connected to an input port of the main circuit of the integrated circuit IP on the semiconductor device (constituting the inner circuitry of the semiconductor device or chip).

The ESD protection circuit formed by the diodes D1 and D2 (first and second diodes) is arranged between the power supply voltages Vdd and Vss, wherein the cathode of the first diode D1 is connected to the potential of Vdd and the anode is connected to a node with further connection to the resistor R and the inner part 2 of the input pad 1, and the cathode of the second diode D2 is connected to this node, and the anode thereof is contacted to the potential of Vss.

The power supply voltages Vdd and Vss constitute predetermined signals as will be further described hereinafter.

The detector 4 is supplied with the potential respectively occurring at the inner and outer part 2 and 3 of the input pad 1 and accordingly receives these signals of the at least two parts 2 and 3 of the bond pad as sensing signals. The detector 4 provides the detection of the bonding condition of the input pad 1 based on the received sensing signals (derived from the predetermined signals) and generates a corresponding output signal or detection signal DET indicative of the detection result. The detection signal or output signal DET of the detector 4 may be subject to any further data evaluation.

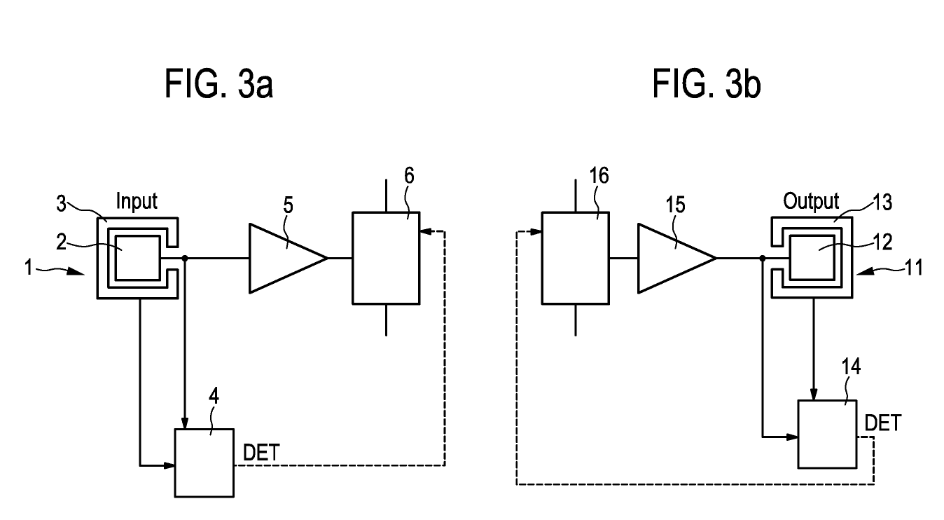

While FIG. 2 shows an exemplary representation of the detection circuitry in conjunction with the input pad 1 as the bond pad the bonding condition of which is to be detected, the block diagram of FIGS. 3a and 3b shows the basic arrangement in conjunction with the input pad 1 and a corresponding output pad 11.

In FIG. 3 the ESD protection circuit (which is shown in further details in FIG. 2) is not shown for simplicity.

Regarding FIG. 3a, the input pad 1 including the inner part 2 and the outer part 3 of at least two parts of the segmented input pad 1 is connected to the detector 4 in a similar manner as it is the case according to FIG. 2, and the detection circuitry may be connected to a buffer 5 and a boundary scan circuit 6 which are equipped to the (digital) integrated circuit IP to detect the failure of the bonding condition (connection) and indicate the detection result to the outside world (for example by means of a PCB). That is, the input pad 1 and specifically the inner part 2 thereof is connected to the boundary scan circuit 6 (for example a boundary scan flip-flop) via the input buffer 5.

As is shown in FIG. 3a, the detection signal DET indicative of the detection result and generated by detector 4 (first detector) is for further data evaluation or for transmission to the outside world fed to the boundary scan circuit 6. This is indicated in FIG. 3a by a dashed line running from the detector 4 to the boundary scan circuit 6.

According to FIG. 3b, a corresponding circuit arrangement is connected to the output pad 11 having an inner part 12 and an outer part 13 in a similar manner as the input pad 1.

It is to be noted that the present invention is not limited to the arrangement of the input pad or the output pad as shown in FIGS. 3a and 3b, as the structure and layout of the inner parts 2 and 12 and the outer parts 3 and 13 are merely an example. Furthermore, the input pad 1 and the output pad 11 may also have a different layout and, therefore, different arrangement and shape of the pad structure and the structure of the respective inner part 2 and 12 and the outer part 3 and 13. It is referred to the exemplary layouts shown in FIGS. 1g to 1k.

The output pad 11 and in particular the inner part 12 and the outer part 13 thereof are respectively connected to a detector 14 which provides a detection of the bonding condition on the output pad 11 and which generates a detection signal or output signal DET indicative of the detected bonding condition on that output pad 11.

The detection circuitry in conjunction with the output pad 11 may be connected, via a buffer 15, to a boundary scan circuit 16. The detection signal DET generated by the detector 14 (second detector) is fed to the boundary scan circuit 16 for further data evaluation or for transmission to the outside world. This is indicated in FIG. 3b by a dashed line running from the detector 14 to the boundary scan circuit 16.

In both cases of FIG. 3a and FIG. 3b, the detection or output signal DET may be transported to the outside world by using the boundary scan circuit 6 and 16, wherein the boundary scan circuits 6 and 16 are arranged in the form of a chain on the semiconductor device having one boundary scan circuit for each bond pad.

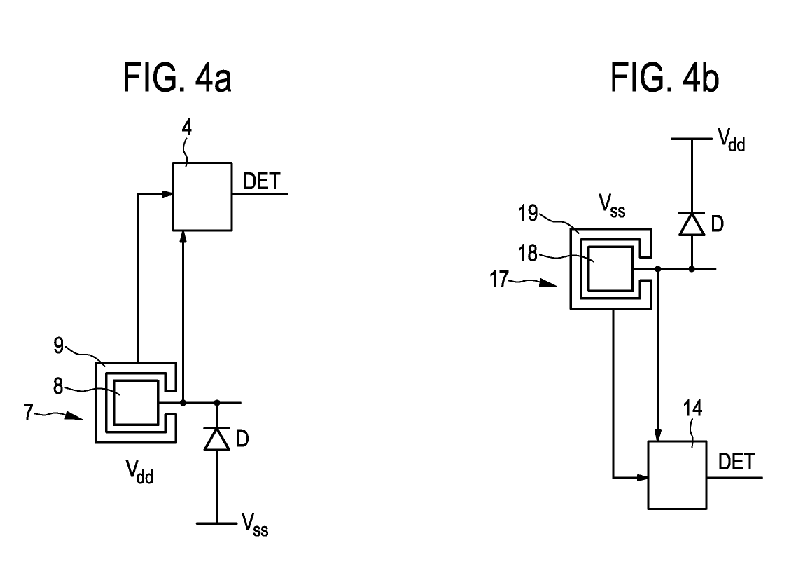

According to the arrangements shown in FIGS. 3a and 3b, the respective detectors 4 and 14 are fed with the potentials applied to the inner parts 2 and 12, respectively, and the outer parts 3 and 13, respectively, constituting the sensing signals, and perform the detection of the bonding condition on the input pad 1 or the output pad 11 based on the sensing signals (derived from the predetermined signals) resulting in the generation of the detection signal DET, which may be fed to the respective boundary scan circuits 6 and 16. The circuit arrangements shown in FIGS. 4a and 4b indicate the situations for power supply pads 7 and 17, respectively having the potential of Vdd and Vss.

According to FIG. 4a, the Vdd-pad 7 has, for example, basically the same structure or layout as the input or output pads 1 and 11 of FIGS. 2 and 3, the Vdd-pad having at least an inner part 8 and an outer part 9 and both parts being electrically separated from each other. The present invention is, however, not limited to the arrangement or layout as described. Both parts are respectively connected to a detector 4 which is arranged for detecting the bonding condition on the Vdd-pad (power supply pad) and which generates a corresponding detection signal DET.

The Vdd potential is supplied to the inner part 8 of the Vdd-pad, and a protection diode D is connected in reversed direction to the potential Vss.

FIG. 4b shows a corresponding arrangement wherein the Vss-pad 17 includes at least an inner part 18 as well as an outer part 19. Both parts 18 and 19 are connected to a detector 14 by respective separate wires, and the detector 14 generates an output signal or detection signal DET indicative of the bonding condition after receiving and evaluating the potential (voltage, sensing signals) at each of the inner part and outer part 18 and 19 of the Vss-pad 17.

The Vss potential is supplied to the inner part 18 of the Vss-pad on the basis of the Vss wiring of the integrated circuit IP. A diode D is connected in the reversed direction between the Vdd potential and the connection to the inner part 18 of the Vss-pad and, thus, to the Vss potential.

The present invention is also applicable in case a plurality of bond pads is provided for power supply for bearing a higher current which necessitates those plural bond pads.

### Second Embodiment

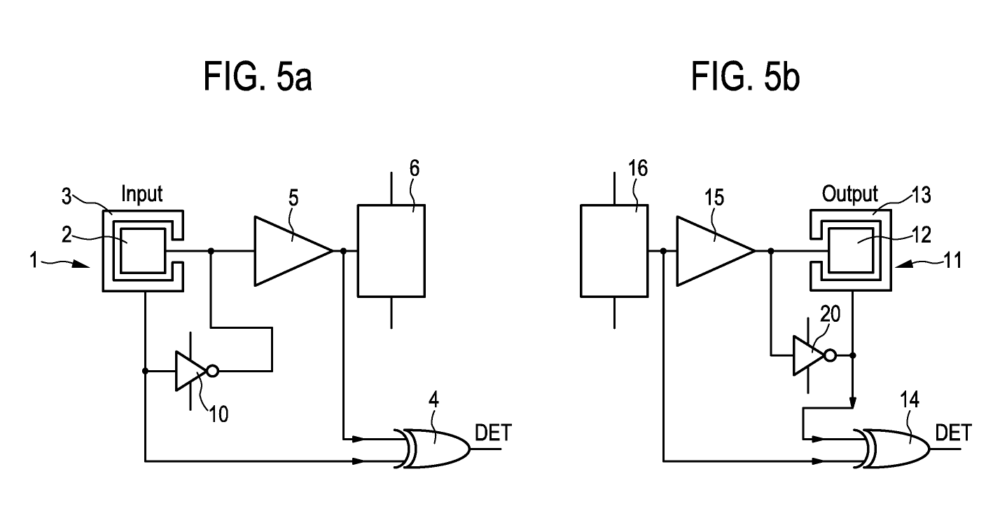

FIGS. 5a and 5b show the arrangement of the circuitry according to a second embodiment of the present invention in connection with respective buffers and boundary scan circuits.

More specifically, FIG. 5a refers to an input pad 1 (segmented or partitioned bond pad) having at least an inner part 2 and an outer part 3, wherein the outer part 3 fully or at least partly surrounds the inner part 2. Both parts 2 and 3 are electrically separated from each other. The layout or structure of the input pad 1 is schematically represented in FIG. 5a with the square or rectangular shape of the inner part 2 and the C-shaped outer part 3 as an example. The present invention is, however, not confined to such a layout of the input pad 1 as the segmented bond pad the bonding condition of which is to be detected, and may be based on various different suitable layouts as, for example, shown in FIGS. 1g to 1k.

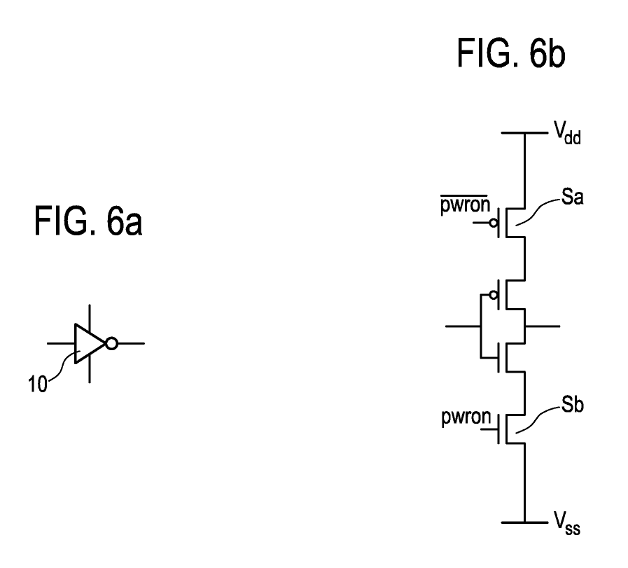

In greater detail, the inner part 2 of the input pad 1 may be connectable to a buffer 5 and, via the buffer 5, to a boundary scan circuit 6. The inner part 2 of the input pad 1 is further connected to an output terminal of an inverter 10, the input terminal of which is connected to the outer part 3 of the input pad 1. That is, the at least two parts 2 and 3 of the input pad 1 are connected by the inverter 10 including power switches Sa and Sb as is shown in FIG. 6. Regarding the circuit structure shown in FIG. 6, in case the power switches Sa and Sb are switched-on (signal pwron=1 according to FIG. 6b), the function is that of a normal inverter. That is, if a logic 1 is applied to one part of the input pad 1, the other part will be inverted, unless the pad is probably contacted by a bump or a solder-ball. Hence, the arrangement shown in FIGS. 5a and 5b in conjunction with FIG. 6 provides the solution for detection of the actual bonding condition, and specifically existence of a good or bad contact to the input pad 1 (FIG. 5a) and the output pad 11 (FIG. 5b). This represents the resistance conditions between the at least two electrically separated parts of the bond pad to be examined.

In other words, a proper or good bump or solder-ball on the input pad 1 would result in short-circuiting the inverter 10 by connecting the at least two parts of the respective pad to be measured.

The outer part 3 of the segmented input pad 1 as the bond pad is in addition to the connection to the input terminal of the inverter 10 also connected to a detector 4 which may, for example, be provided as a logical EXOR gate or any other suitable logical gate with a corresponding function, such as the comparison function of comparing at least two input signals in view of their logical level. The other terminal of the detector 4 is connected to the output side of the buffer 5 which corresponds to the input side of the boundary scan circuit 6. That is, the detector 4 receives the output signal of the buffer 5 as well as the potential applied to the outer part 3 of the input pad 1. These inputs to the detector 4 are sensor signals on the basis of which the detection process is carried out. In greater detail, the sensor signals directly or indirectly received from the at least two parts 2 and 3 of the bond pad 1 are compared in the detector 4 (based on EXOR logic), and specifically the input bit to the input pad 1 (outer part 3 of the input pad 1) is compared with the output bit output by the input buffer 5 and resulting from the inner part 2 of the input pad 1, and if a bad contact has been made, i.e. if the bump or solder-ball has no good or sufficient contact to the at least two parts of the input pad 1, the output signal DET will be logic 1. However, if a good contact is provided, resulting in a short-circuiting of the inverter 10, then the output signal DET of the detector 4 will be logic 0, indicating the good or sufficient contact. That is, when said potentials of said at least two parts of said bond pad have the same logical level indicated by basically corresponding sensing signals, then a good bonding condition (proper contact) is detected.

The detector 4 with its direct or indirect connections to the plural parts of the input pad 1 is therefore adapted for detecting the bonding condition occurring at the input pad 1 of the semiconductor device, and specifically determines the resistance occurring between the inner part 2 and the outer part 3 of the input pad 1, preferably by comparing the detector input signals (the sensing signals) in view of their logical level (potential). The logical evaluation of the signals received by the detector 4 results in the detection signal DET indicative of the bonding condition. This output signal DET can be fed to the boundary scan circuit 6. Therefore, a connection is omitted to simplify representation.

As is shown in FIG. 5b, the segmented output pad 11 having the inner part 12 and the outer part 13 is in a similar manner connected to the boundary scan circuit 16 via the buffer 15 (output buffer). Both the inner part 12 and the outer part 13 of the output pad 11 are connected by an inverter 20 wherein the output signal of the buffer 15 corresponding to the potential of the inner part 12 forms the input signal for the inverter 20. The output signal of the inverter 20 is both connected to the outer part 13 and one input terminal of a detector 14. The detector 14 may, for example, be provided in the form of or may comprise a logic EXOR gate.

The other input terminal of the detector 14 receives the output signal of the boundary scan circuit 16 which represents the input signal of the buffer 15.

Regarding the operation of the circuit arrangement shown in FIG. 5b, a bit will be put on the output of the boundary scan circuit (and will be fed to the buffer 15), and be inverted by the inverter 20 after switching power switches of the inverter 20 on. The inverter 20 has the same structure as the inverter 10, the structure of which is shown in FIG. 6b. The detector 14 is adapted for comparing the input bit on part of the pad (inner part 12) with the result of the other part of the pad (outer part 13), so that in case of a good bump or solder-ball the output signal DET of the detector 14 is 0 (indicating a good contact, the inverter being short-circuited), and in case of a bad contact (open contact) the output signal DET of the detector 14 is logic 1. Hence, the detector 14 receives the sensing signals directly or indirectly from the at least two parts 12 and 13 of the bond pad and performs the detection process. Since according to the second embodiment as shown in FIGS. 5a, 5b and 6a, 6b, the detectors 4 and 14, respectively, (and being, for example, represented by a logic EXOR gate) are always parallel to the respective input pad 1 or output pad 11, and since also the inverter input (gate) for the input pad 1 is present even when switched-off, these gates represent an extra capacitive load. Also the inverter will be short-circuited in case of a good contact.

The present invention according to the above embodiments provides a detection circuitry which allows the reliable and easy testing of the actual bonding conditions of bonding pads irrespective whether the bonding pads are used for inputting or outputting data or for the connection of power supply lines. The bonding pads having a segmented layout are examined by the circuitry on the semiconductor device without further outside detection means. A reliable detection result on the actual bonding conditions can be obtained. The detection circuitry may easily be compatible with the on-chip boundary scan system, exhibiting a complete on-chip detection solution. By means of the boundary scan system, the detection result obtained can be supplied to any device outside the semiconductor device for further data evaluation.

### Third Embodiment

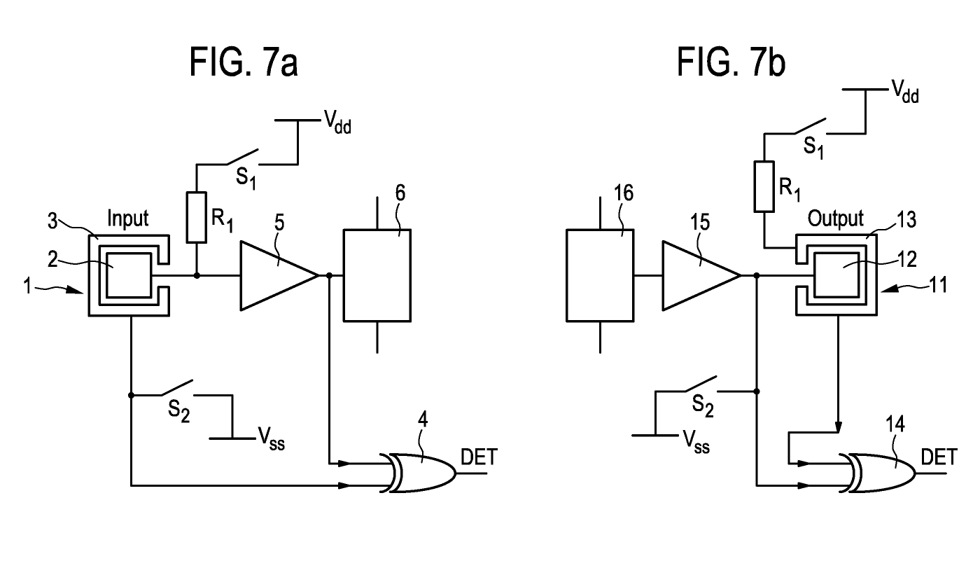

Accordingly, the arrangement of FIGS. 7a and 7b shows a further improved detection circuitry according to the present invention and representing a third embodiment thereof.

More specifically, FIG. 7a shows an improved detection circuitry based on the principal circuit of FIG. 5a, the circuit arrangement of FIG. 7a now using first and second switching elements S1 and S2 and a (first) series resistor R1. Specifically, the inner part 2 of the segmented input pad 1 is connected to the Vdd potential by means of the series resistor R1 and the first switching element S1. Similar to the arrangement of FIG. 5a, the inner part 2 may also be connected to a buffer 5 (input buffer), and via this buffer 5 to a boundary scan circuit 6 which forms part of a plurality of boundary scan circuits arranged in the integrated circuit on the semiconductor device. Moreover, the outer part 3 of the input pad 1 (bond pad) is connected to the potential Vss via the second switching element S2, and is also connected to one input terminal of a detector 4 which may, for example, be provided in the form of a logic EXOR gate. The other input terminal of the detector 4 is connected to the connection between the buffer 5 and the boundary scan circuit 6.

As described in conjunction with the previous embodiments, the detector 4 provides a detection process and a data evaluation of the sensing signals (potentials) supplied and input to its input terminals and generates a detection signal DET indicative of the detection result, and more specifically indicative of the bond condition of the input pad 1.

Regarding the operation of the circuit arrangement shown in FIG. 7a, after closing the switching elements S1 and S2 (switching the switching elements ON) the input signal of the buffer 5 becomes 0 (representing a good contact) or 1 (representing a bad, open or insufficient contact). The detector 4 (for example including the EXOR gate) compares the logic levels of both parts 2 and 3 of the input pad 1 supplied as the sensing signals, and the detection signal DET of the detector 4 indicates a good or proper contact, that is, an appropriate bump or solder-ball if DET=0, and indicates the bad (open) contact if the detection signal DET=1.

The circuit arrangement shown in FIG. 7b indicates a corresponding situation at a segmented output pad 11 which also has at least an inner part 12 and an outer part 13 and having as an example the structure as presented in the figure. According to the circuit arrangement, the outer part 13 of the output pad 11 surrounding the inner part 12 is connected via a series resistor R1 and a first switching element S1 to the Vdd potential, and the potential applied to the outer part 13 is also fed to one input terminal of a detector 14 which may be exemplified as an EXOR gate. The inner part 12 of the output pad 11 is on the one hand connected to the other input terminal of the detector 14 and on the other hand via a buffer 15 (output buffer) to a boundary scan circuit 16. The connection to the other terminal of the detector 14 can be connected to the Vss potential by means of a second switching element S2. That is, when the two switching elements S1 and S2 are closed (switched-on), the output signal of the buffer 15 is pulled to the Vss potential representing logic 0, and the outer part 13 of the output pad 11 becomes 0 (good contact) or 1 (bad contact). Hence, the detection signal DET output by the detector 14 corresponds to the output signal DET of the detector 4 in conjunction with the analysis of the bonding situation (bonding condition) of the input pad 1. The switching elements S1 and S2 (here in conjunction with series resistor R1) constitute a supplying unit for supplying predetermined signals to the at least two parts 2 and 3 of the input pad 1 (bond pad to be examined), wherein the predetermined signals include the power supply voltages (potentials) Vdd and Vss. At least one of the predetermined signals is supplied by the supplying unit to at least one of the at least two parts 2 and 3 of the input pad 1. In the present case, one of the predetermined signals Vdd and Vss is supplied to one of the plural parts of the input pad 1, and the other predetermined signal is supplied to the respective other part.

Regarding FIGS. 7a and 7b and the corresponding circuit arrangement, the detector 4 or 14, respectively, is always parallel to the pad, so that, for example, the EXOR gate included in the detectors 4 and 14 is parallel to the pad. The output signal of the buffer is directly pulled to the Vss potential, and if the buffer is to output logic 1, then a large current may flow through the switched-on P-MOS transistor (not shown) in the end-stage of the buffer 15.

Hence, the supplying unit serves for supplying the at least two parts of the bond pad to be examined with different potentials (different predetermined signals). That is, when said potentials of said at least two parts of said bond pad have the same logical level indicated by basically corresponding sensing signals (the parts are short-circuited by a proper bonding), then a good bonding condition (proper contact) is detected.

### Fourth Embodiment

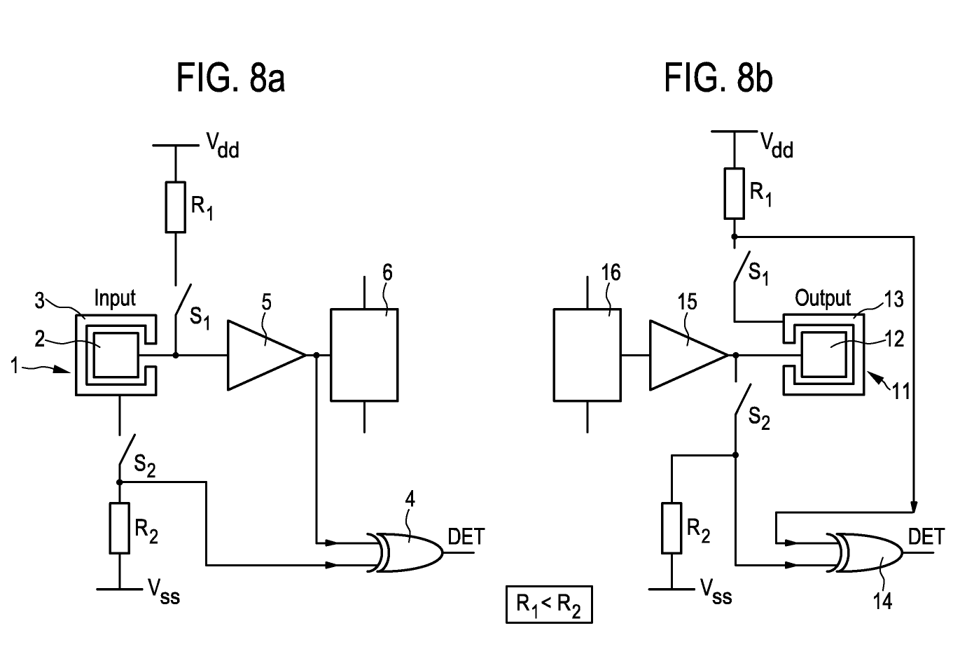

FIGS. 8a and 8b show a further circuit arrangement of the detection circuitry for detecting bonding conditions on segmented bond pads of a semiconductor device according to the present invention.

As is shown in FIG. 8a, an inner part 2 of the at least two parts of a segmented (partitioned) input pad 1 is connected to the Vdd potential via a first switching element S1 and a first series resistor R1. The inner part 2 of the input pad 1 may further be connected to a buffer 5 (input buffer) and to a boundary scan circuit 6. An outer part 3 of the input pad 1 is connected to the Vss potential via a second switching element S2 and a second series resistor R2. A detector 4 which may be provided in the form of a logic EXOR gate, is connected with one input terminal to the connection portion between the second switching element S2 and the second series resistor R2. The other input terminal of the detector 4 is connected to the output signal of the buffer 5. The layout of the input pad is not confined to the shape as shown in the figures, but any other segmented shape may be adopted without departing from the present invention.

Regarding the operation of the circuit arrangement according to FIG. 8a, testing can be performed by closing the first and the second switching elements S1 and S2. This testing refers to the detection of the bonding condition of the segmented input pad 1. It is to be noted that a central control means (not shown in the figures) may be provided for setting a test mode of operation and controlling the switching state of the switching elements S1 and S2 in a corresponding manner, as well as a normal (regular) operation of the semiconductor device. The detector 4 is not permanently connected to the bond pad in the form of the input pad 1, as this will only occur during testing when the switching elements S1 and S2 are switched-on (closed state thereof). That is, after closing of the switching elements S1 and S2, and in conjunction with the further condition R1<R2, the output signal of the buffer 5 will become 1 (Vdd potential applied to the inner part 2 of the input pad 1), whereas the outer part 3 of the input pad 1 will become the logical level 1 indicating a good or proper contact proper bump or solder ball short-circuiting the at least two parts), or 0 (Vss potential supplied to the outer part 3 via the supplying unit represented in the present embodiment by switching element S2 and series resistor R2), indicating a bad or insufficient contact (further specifying a higher resistance occurring between the at least two parts of the bond pad in question).

FIG. 8b shows a corresponding arrangement wherein in particular an outer part 13 of the at least two parts of an output pad 11 is connected to the Vdd potential via a first series resistor R1 and a first switching element S1 (representing the supplying unit). The connecting portion between the first series resistor R1 and the first switching element S1 is connected to a first input terminal of a detector 14. The other input terminal of the detector 14 is connected via a second switching element S2 to the output signal of a buffer 15 representing the potential of an inner part 12 of the output pad 11. The further input terminal of the detector 14 is further connected to the Vss potential via a second series resistor R2. When detection of the bonding condition on the output pad 11 is to be performed and when the switching elements S1 and S2 are switched-on (i.e. are closed), the outer part 13 of the output pad 11 will become logical level 1, and the output of the buffer 15 becomes logic level 1 indicating a good contact (proper bump or solder-ball) or 0, indicating a bad contact. The detection signal DET of both detectors 4 and 14 becomes the same as that described in conjunction with the third embodiment.

The output pad 11, and in particular the inner part 12 thereof may further be connected to a boundary scan circuit 16 via the buffer 15 (output buffer). The condition R1<R2 is also applicable.

The present invention is not limited to the shape an arrangement of the segmented bond pads as shown in the figures.

### Fifth Embodiment

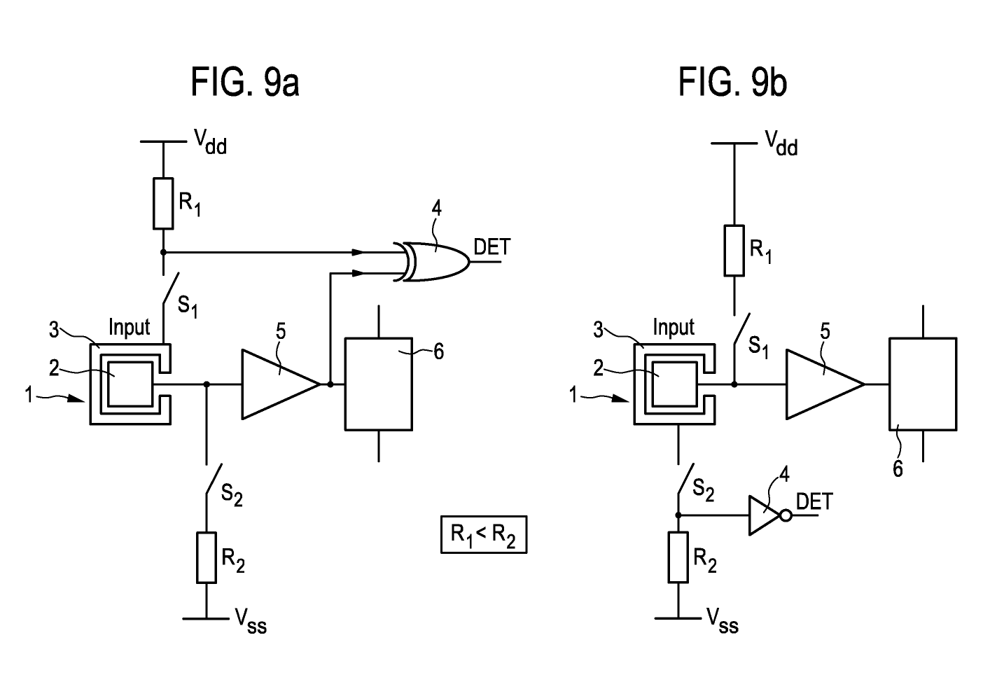

FIGS. 9a and 9b show a circuit arrangement of the detection circuitry for detecting bonding condition such as bad contacts on segmented bond pads according to a fifth embodiment of the present invention, and specifically alternatives for the input pad of FIG. 8a is shown in FIGS. 9a and 9b, both figures being directed to input pads 1.

More specifically, FIG. 9a shows a circuit arrangement wherein an outer part 3 of the input pad 1 is connected to the Vdd potential via a first switching element S1 and a series resistor R1. An inner part 2 of the input pad 1 is connected to the Vss potential via a second switching element S2 and a second series resistor R2. The first switching element S1 and the series resistor R1 as well as the second switching element S2 and the second series resistor R2 constitute the supplying unit for supplying predetermined signals to the at least two parts 2 and 3 of the bond pad. The inner part 2 of the input pad 1 may be connected to a buffer 5 (input buffer) and further to a boundary scan circuit 6 in a similar manner as it is the case in previous embodiments.

The circuitry includes a detector 4 which may be provided, as an example, by a logic EXOR gate. A first input terminal of the detector 4 is connected to the connection portion between the first series resistor R1 and the first switching element S1, that is, is connected to the outer part 3 of the input pad 1 via the first switching element S1. The further input terminal of the detector 4 is connected to the output signal of the buffer 5.

Hence, according to FIG. 9a, the detector 4 is connected to the Vdd potential (via the first series resistor R1), and the output of the buffer 5 is dependent on the contact provided by the bump or solder-ball, and thus from the bonding condition on the input pad 1. The detection signal DET output by the detector 4 and indicative of the detection result and specifically of the bonding condition is as given above in conjunction with the third and fourth embodiments.

The arrangement shown in FIG. 9b of the fifth embodiment provides a simplification in that the detector 4 is not connected to the Vdd potential by means of the first series resistor R1 but is connected to the Vss potential by means of the second series resistor R2. That is, the detector 4 is connected to a connecting portion between the second switching element S2 and the second series resistor R2.

Moreover, the detector 4 may be provided, for example, by or may include an inverter, and the output signal or detection signal DET of the detector 4 provided for example in the form of the inverter is the same as given above in conjunction with the third and fourth embodiments.

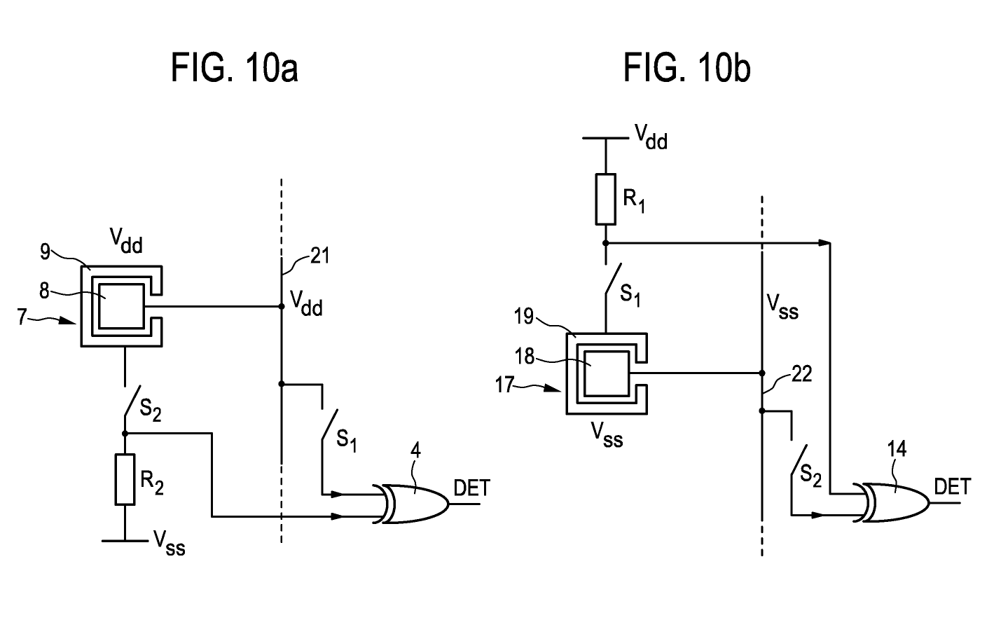

Regarding the circuit arrangement for obtaining the detection circuitry for detecting bonding conditions such as bad contacts of the power supply pads for the Vdd potential or Vss potential, respectively, it is referred to the arrangements shown in FIGS. 10a and 10b of the fifth embodiment.

According to FIG. 10a, the inner part 8 of the Vdd pad 7 which consists of at least two parts, is connected to the Vdd line (Vdd power supply line) 21, usually provided in an integrated circuit of the semiconductor device in the form of a Vdd ring. By means of a first switching element S1 the first input terminal of a detector 4 is connected to the Vdd line 21. The outer part 9 of the Vdd pad 7 is connected to the Vss line (Vss power supply line) 22 (Vss potential) by means of a second switching element S2 and a second series resistor R2. The connection portion between the second switching element S2 and the second series resistor R2 is connected to the other input terminal of the detector 4. The detector 4 can be provided, for example, as or may include an EXOR gate, and can generate an output signal or detection signal DET indicative of the potential conditions and, thus, on the bonding conditions on the Vdd pad 7.

Regarding the operation of the circuit arrangement shown in FIG. 10a, since the inner part 8 of the Vdd pad 7 is connected to the Vdd line 21 (Vdd ring, power rail), the detector 4 may be connected by closing the first and second switching elements S1 and S2 for carrying out the test process, and the detection signal DET output by the detector 4 is the same as in the cases of the third to fifth embodiments. That is, DET=0, if a good contact (proper or sufficient bump or solder-ball on the bond pad) is detected, and DET=1, in case a bad contact has been made.

FIG. 10b shows a similar arrangement in conjunction with the Vss potential (power supply) which is connected to an inner part 18 of the Vss pad 17. The outer part 19 thereof is connected by means of a first switching element S1 and a first series resistor R1 to the Vdd potential. One input terminal of a detector 14 (which may, for example, be provided in the form of an EXOR gate) is connected to a connection portion between the first series resistor R1 and the first switching element S1.

The other input terminal of the detector 14 is connected via a second switching element S2 to the Vss potential and, thus, to the inner portion 18 of the Vss pad 17.

The detector 14 is adapted for outputting a detection signal DET similar to the resulting detection signal as given above in conjunction with FIG. 10a. Moreover, the first switching element S1 and the series resistor R1 as well as the second switching element S2 and the second series resistor R2 may constitute the supplying unit for supplying predetermined signals to the at least two parts of the bond pad. According to the representation in FIGS. 10a and 10b, the respective switching element S1 or S2 which is not actually used as a supplying unit therefore provides a connection of a respective input terminal of the detector 4 or 14 to one of the at least two parts of the pond pad, and, thus, to supply the detector 4 and 14 with the respective sensing signal.

### Sixth Embodiment

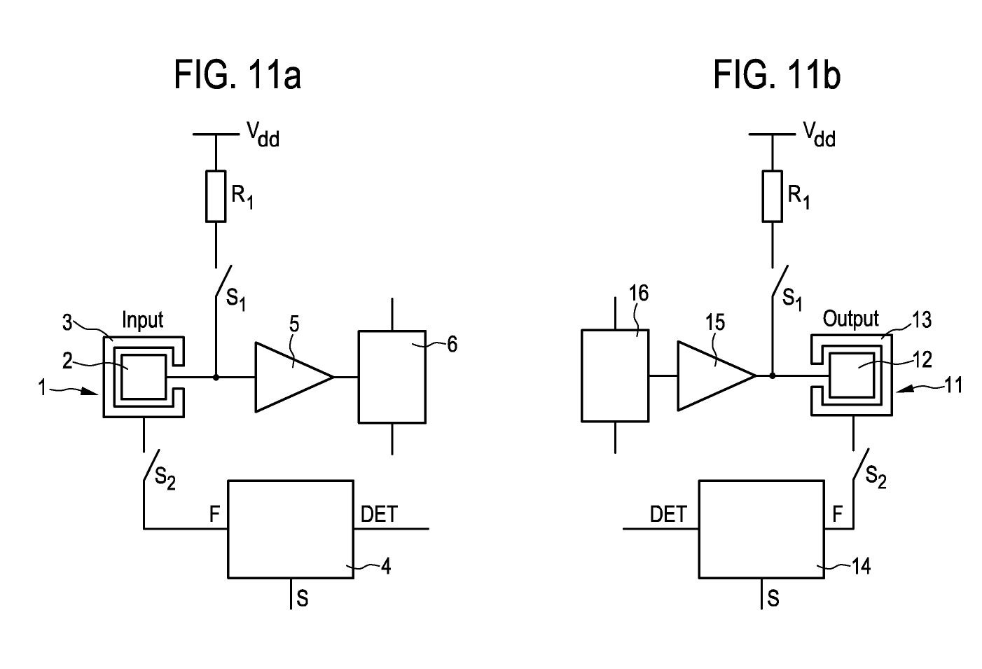

With reference to the circuit arrangements shown in FIGS. 11a and 11b a sixth embodiment of the present invention is described.

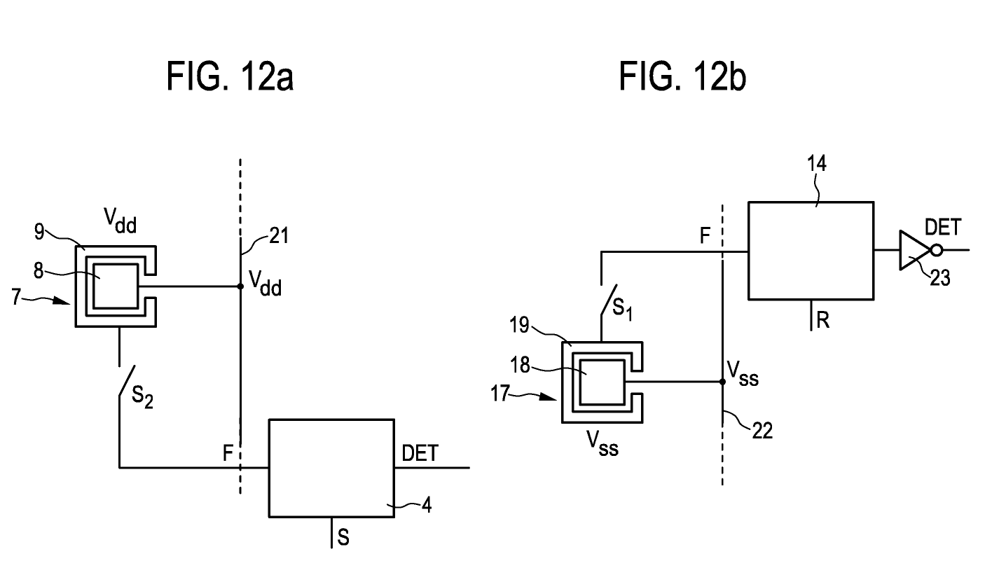

The circuit arrangement shown in FIGS. 11a and 11b for a segmented or partitioned input pad 1 and a segmented or partitioned output pad 11, respectively, and according to FIGS. 12a and 12b for the respective power supply pads (Vdd pad and Vss pad) use a set-latch (S-latch) or a reset-latch (R-latch). These latches represent the detectors 4 and 14 of the previous embodiments.

According to FIG. 11a, an inner part 2 of the input pad 1 is on the one hand connected to the Vdd potential by means of a first switching element S1 and a first series resistor R1, and on the other hand may be connected to a buffer 5 (input buffer) and a corresponding boundary scan circuit 6. An outer part 3 of the segmented input pad 1 having at least two parts, is connected by means of a second switching element S2 to the detector 4, provided in this embodiment in the form of an S-latch.

In a similar manner, an inner part 12 of the segmented output pad 11 is connected to the Vdd potential by means of a first switching element S1 and a first series resistor R1. The inner part 12 may further be connected to a buffer 15 (output buffer) and a corresponding boundary scan circuit 16. An outer part 13 of the output pad 11 is connected to a detector 14 by means of a second switching element S2. The detector 14 is according to the present embodiment provided in the form of the S-latch. In both cases of FIGS. 11a and 11b the detectors 4 and 14 (the S-latches) provide a detection of the bonding condition on (and representing the resistance conditions between the at least two parts of) the respective input pad 1 or output pad 11, and generate a detection signal DET indicative of the bonding conditions sensed.

More specifically, while by means of the first switching element S1 and the first series resistor R1 a logical 1 is put on the inner part 2 or 12 of the respective pads, and since a respective node F of the S-latches in both cases of FIGS. 11a and 11b is connected to the outer parts of the respective pads through the second switching element S2, the node F is set to a logical 0, and the output signal DET (detection signal) is then set to logical 1 by the said signal S supplied to the detectors 4 and 14. If the pad is well-connected by a proper or sufficient bump or solder-ball, resulting in short-circuiting the outer parts 3 and 13 with the respective inner parts 2 and 12 of the pads 1 and 11 (represented by a minimal resistance between the at least two parts of the bond pad), this will force the input terminal F of each detectors 4 and 14 to switch to logical 1. Therefore, the output signal (detection signal) DET of the detectors 4 and 14 (the S-latches) will toggle (will become logical 0). If the respective input pad 1 or output pad 11 is not probably connected (no suitable or sufficient bump or solder-ball), the node F of the detectors 4 and 14 will remain at logical 0, and the detection signal DET will remain at logical 1. Thus, after the switching elements S1 and S2 are closed, the detection signal DET is given as earlier: DET=0 (toggled), representing a good or sufficient contact caused by an optimized or suitable bump or solder-ball, and DET=1, if a bad contact has been made (open contact between inner parts 2 or 12 and outer parts 3 or 13, respectively).

According to the sixth embodiment, at least one predetermined signal (such as the voltage signals Vdd and Vss) is supplied via the supplying unit (switching elements in conjunction with series resistors) to at least one of the at least two parts 2, 3, 12 and 13 of the respective input or output pad 1 or 11 forming the bond pad to be examined.

A corresponding situation is defined according the circuit arrangement shown in FIG. 12a in conjunction with the Vdd pad 7 (power supply pad).

According to FIG. 12a, the Vdd pad 7 having at least an inner part 8 and an outer part 9 thereof, has the inner part 8 connected to the Vdd line 21 (Vdd potential, Vdd ring), whereas the outer part 9 is connected through the second switching element S2 to the node of the detector 4 which may be provided in the form of an S-latch (set-latch). The detector 4 includes the input terminal (node F) for entering data to the latch function, and the output signal DET (detection signal) generated by the detector 4 is indicative of the bonding condition of the Vdd pad 7. The operation of the circuit arrangement shown in FIG. 12a is as given for FIGS. 11a and 11b.

Node F (input terminal to the detector 4) is set to logical 0, and the detection signal DET is then set to logical 1 by the said signal S for controlling the latch function. If the Vdd pad 7 is well-connected, that is, in case a proper or suitable bump or solder-ball is applied, the outer part 9 thereof will force the node F to switch to logical 1. Therefore, the output signal or detection signal DET will toggle (and will become 0). However, if the Vdd pad 7 is not probably connected (open or insufficient contact), the node F of the detector 4 will remain at logical 0, and the detection signal DET will remain logical 1. Hence, after the second switching element S2 is closed, the detection signal DET indicating the bonding conditions is as given above.

A slightly different situation holds for the segmented Vss pad 17 according to the circuit arrangement shown in FIG. 12b. In this case, by means of a first switching element S1, an outer part 19 of the Vss pad 17 is connected at an input terminal F to a detector 14 which may be provided in the form of or include the R-latch (reset-latch). A further input terminal R serves for controlling the latching operation of the detector 14. The detector 14 is closely connected to a further inverter 23 for inverting the direct output signal of the detector 14 to obtain the resulting detection signal DET as the output signal of the inverter 23. An inner part 18 of the Vss pad is connected to the Vss potential, and specifically to a Vss line 22 (Vss ring).

With the input terminal F of the detector 14 (R-latch) being connected to the outer part 19 through the first switching element S1, the node F is reset to logical 1, and the detection signal DET (output by the extra inverter 23) is therefore also reset to logical 1 by the reset signal R input to the detector 14. If the Vss pad 17 is probably connected, resulting in a short-circuiting of the outer part 19 and the inner part 18 of the Vss pad 17, this will force the node F to switch to logical 0. Therefore, the detection signal DET will toggle (will become 0). If the pad, however, is not properly connected, indicating a bad bonding condition of the pad, the node F of the detector 14 will remain at logical 1, and the detection signal will remain at logical 1. Hence, after the first switching element S1 is closed, the detection signal DET is as given above.

According to the present invention, the switching elements used in the various embodiments may be provided in the form of MOS transistors or pass gates. The detector output signal DET may be coupled to the boundary scan circuits (boundary scan flip-flops) by using an additional input of a multiplexer (MUX).

According to the fourth to sixth embodiments, the supplying unit serves for supplying the at least two parts of the bond pad to be examined with different potentials (different predetermined signals). That is, when said potentials of said at least two parts of said bond pad have the same logical level (voltage range indicating a particular logical level) indicated by basically corresponding sensing signals (the parts are short-circuited by a proper bonding), then a good bonding condition (proper contact) is detected. The sensing signals are then derived from the predetermined signals (Vdd or Vss) supplied to the plural parts of the bond pad.

### MODIFICATIONS

Referring again to the first embodiment and the arrangement of the segmented bond pads as shown in FIGS. 1g to 1k, the bonding pads in question consist of at least two parts, mainly an inner part and an outer part thereof, the outer part surrounding the inner part of the respective pad except a certain portion which is provided in the form of a gap along which a connection wire to the inner part is running. In this case, the wiring to the at least two parts of the bond pad can be provided in the same layer without any undesired crossing or changing of layers.

Alternatively, in case the wiring (connection paths) to the various parts of the pad in question can be configured to run in different metal layers of the semiconductor device having a connection from one layer to the other layer by predetermined via holes, then also a crossing-free wiring to the various parts of a bond pad (the parts being separated or isolated from each other) can be obtained. In this case, the outer part of the bonding pad may be provided as a closed ring without any gap or discontinuity, so that the active area of the bond pad (upon which a bump or a solder-ball can be applied) can be increased. That is, when at least an inner part and an outer part of a bonding pad are considered, the wiring to the inner part is mainly provided in a different layer than the wiring to the outer part of the respective pad.

Furthermore, the advantages obtained in conjunction with the third to sixth embodiments are the same as that of the first and second embodiments. While the present invention has been illustrated and described in detail in the drawings and the foregoing descriptions, such illustrations and descriptions are to be considered illustrative or exemplary and not restrictive, and the present invention is not limited to the disclosed embodiments.

Other variations to the disclosed embodiments can be understood and effected by those skilled in the art in practicing the claimed invention, from a study of the drawings, the disclosure and the appended claims in which the reference signs are not to be interpreted as limiting the scope of the present invention.

1. Detection circuitry for detecting bonding conditions on bond pads of a semiconductor device, including:
a segmented bond pad having at least two parts being electrically separated from each other,
a supplying unit being adapted for supplying predetermined signals to at least one of the at least two parts of the segmented bond pad, and
a detector being adapted for receiving from at least one of the at least two parts of the segmented bond pad sensing signals derived from said predetermined signals and determining said bonding conditions based on said received sensing signals.

2. Detection circuitry according to claim 1, wherein said predetermined signals supplied by said supplying unit include different voltage signals to be supplied to the at least two parts of said segmented bond pad to obtain different potentials between the at least two parts.

3. Detection circuitry according to claim 1, wherein said segmented bond pad includes at least a first and a second part, and at least one of the first and second parts is connectable to a boundary scan circuit arranged on the semiconductor device.

4. Detection circuitry according to claim 1, wherein said supplying unit comprises switching elements assigned to each of said at least two parts of said segmented bond pad and being adapted to supply said predetermined signals to said parts of said segmented bond pad assigned thereto, when said switching elements are closed.

5. Detection circuitry according to claim 1, wherein
said detector comprises at least two input terminals, and
said supplying unit comprises switching elements assigned to each of said at least two parts of said segmented bond pad and being adapted to supply said predetermined signals to said parts of said segmented bond pad assigned thereto and to connect at least one of said input terminals of said detector with one of said parts of said segmented bond pad, when said switching elements are closed.

6. Detection circuitry according to claim 1, wherein said detector being adapted for carrying out a comparison process for comparing said received sensing signals, and to generate a detection signal indicative of said detected bonding condition.

7. Detection circuitry according to claim 6, wherein said detection signal output by said detector indicates a good bonding condition, when the sensing signals of each of the at least two parts of said segmented bond pad have the same logical level.

8. Detection circuitry according to claim 2, wherein said supplying unit being adapted for supplying two different voltage signals via series resistors to said at least two parts of said segmented bond pad.

9. Detection circuitry according to claim 1, wherein said at least two parts of said segmented bond pad include at least an inner part and an outer part surrounding fully or at least partially said inner part of said segmented bond pad.

10. Detection circuitry according to claim 1, wherein said detector comprises a logical EXOR gate.

11. Detection circuitry according to claim 1, wherein said detector being adapted for receiving said sensing signal from one of the at least two parts of said segmented bond pad and said detector comprising an inverter.

12. Detection circuitry according to claim 1, wherein said detector including at least two input terminals, and said segmented bond pad being adapted for connection to at least two power lines for providing said predetermined signals, and wherein at least one of said input terminals of said detector being connected to one of said at least two power lines.

13. Detection circuitry according to claim 1, wherein a switching element is provided, and said detector includes an S-latch circuit, and wherein from one of said at least two parts of said segmented bond pad via said switching element a sensing signal of said part is supplied to said detector when said switching element is closed.

14. Detection circuitry according to claim 1, wherein a switching element is provided, and one of said at least two parts of said bond pad is supplied with one of said predetermined signals, and said detector including a latch circuit which is supplied via said switching element with the sensing signal of said other part of said at least two parts of said bond pad when said switching element is closed, and being adapted for generating a detection signal indicative of said bonding condition.

15. Detection circuitry according to claim 14, wherein said latch circuit is one of an S-latch and an R-latch.
